(19) United States
(12) Patent Application Publication
(10) Pub. No.: US 2025/0309812 A1
(43) Pub. Date: Oct. 2, 2025

(54) SMART MOTOR CONTROL CENTER WITH PREDICTIVE MAINTENANCE FUNCTION

(71) Applicant: ITS CO., LTD., Ulsan (KR)

(72) Inventor: Young Kyu LEE, Ulsan (KR)

(21) Appl. No.: 18/864,556

(22) PCT Filed: Oct. 19, 2022
(86) PCT No.: PCT/KR2022/015978

§ 371 Date: Dec. 5, 2024

(30) Foreign Application Priority Data
May 20, 2022 (KR) 10-2022-0062280

(51) Int. Cl. H02P 29/032

(52) U.S. Cl. CPC H02P 29/032

(57) ABSTRACT

The present invention relates to a motor control center having a compact structure, which is capable of performing predictive maintenance for a motor connected to the motor control center by having, integrally formed with the motor control center in order to detect the operation state of the motor in real time: a current measurement module which measures a current flowing in a power supply line for supplying power from the motor control center to the motor; a detection server which detects the state of the motor on the basis of the measurement information of the current measurement module; and an image output module which outputs and provides the detection information of the detection server in the form of an image.

### CROSS-REFERENCE TO RELATED APPLICATIONS

This application is the National Stage filing under 35 U.S.C. 371 of International Application No. PCT/KR2022/015978, filed on Oct. 19, 2022, which claims the benefit of K.R application No. 10-2022-0062280, filed on May 20, 2022, the contents of which are all hereby incorporated by reference herein in their entirety.

### TECHNICAL FIELD

The present disclosure relates to a smart motor control center with a predictive maintenance function, and more particularly, to a smart motor control center with a predictive maintenance function which proposes a motor control center having a compact structure, which is capable of performing predictive maintenance for a motor connected to the motor control center by having, integrally formed with the motor control center in order to detect the operation state of the motor in real time, a current measurement module which measures a current flowing in a power supply line for supplying power from the motor control center to the motor, a detection server which detects the state of the motor on the basis of the measurement information of the current measurement module, and an image output module which outputs and provides the detection information of the detection server in the form of an image, thereby significantly saving a cost consumed to construct a predictive maintenance system in the related art and ensuring an excellent usability of a device without requiring a separate space for constructing the predictive maintenance system.

### BACKGROUND ART

Generally, a motor control center (MCC) refers to a system which safely protects motors installed in various industrial facilities and related loading devices and has a function of distributing a low-voltage electricity supplied from a transformer to a motor and monitoring and blocking overcurrent.

In recent years, a predictive maintenance system which detects a real-time operation state of a motor which is connected to a motor control center to detect an abnormal state before a failure of the motor occurs is being proposed to prevent huge cost losses due to downtime caused by the motor failure.

However, the predictive maintenance system as described above requires to construct a detector which is installed in a motor to measure and detect a state of the motor, a management server provided with various detectors to determine and detect the state of the motor on the basis of detection information measured by the detector, and a wired/wireless communication line constructed to transmit and receive information of the detector and the management server. Therefore, due to this characteristic, in order to construct the predictive maintenance system, not only too much construction cost, but also a predetermined installation space is required so that actually, there are spatial constraints and financial difficulties in implementing the predictive maintenance system.

Further, the predictive maintenance system constructed as described above needs to be operated and managed by management personnel so that a large amount of additional labor costs is required to operate the system, which makes it difficult to construct the system realistically.

### SUMMARY

### Technical Problem

The present disclosure has been proposed to solve the above-described problems and an object is to provide a smart motor control center with a predictive maintenance function which proposes a motor control center having a compact structure, which is capable of performing predictive maintenance for a motor connected to the motor control center by having, integrally formed with the motor control center in order to detect the operation state of the motor in real time, a current measurement module which measures a current flowing in a power supply line for supplying power from the motor control center to the motor, a detection server which detects the state of the motor on the basis of the measurement information of the current measurement module, and an image output module which outputs and provides the detection information of the detection server in the form of an image, thereby significantly saving a cost consumed to construct a predictive maintenance system in the related art and ensuring an excellent usability of the device without requesting a separate space for construction of the predictive maintenance system.

Moreover, the smart motor control center with a predictive maintenance function is provided to provide the compact structure in which the current measurement module, the detection server, and the image output module are integrally formed with the motor control center to minimize management manpower required for operating and managing the device, thereby ensuring excellent usability of the device

### Technical Solution

In order to achieve the above-described objects, according to an aspect of the present disclosure, a smart motor control center with a predictive maintenance function is a motor control center (MCC) which protects a motor and a related loading device and includes one or more current measurement modules which measure a real-time current value flowing in a power line for supplying power to the motor and transmit measured current value information to a detection server; the detection server which detects a real-time operation state of the motor on the basis of current value information measured and transmitted from the current measurement module; and an image output module which outputs and provides the real-time operation state of the motor detected by the detection server in the form of an image.

Further, the detection server includes a generation module which lists current values measured and transmitted from the current measurement module over time to construct a real-time current waveform for the motor, a storage module which stores and manages a reference current waveform which is constructed by listing current values consumed in the motor in a normally driven state of the motor over time, and a detection module which detects an operation state of the motor in real time on the basis of a real-time current waveform of the motor constructed in the generation module and the reference current waveform stored in the storage module.

Further, the detection server further includes a matching rate measurement module which measures a matching rate of the real-time current waveform to the reference current waveform by matching the real-time current waveform constructed in the generation module and the reference current waveform stored in the storage module and a threshold input module which inputs and sets a threshold value for the matching rate of the real-time current waveform to the reference current waveform and a threshold value for a current value of the current waveform and when a matching rate measured by the matching rate measurement module exceeds the threshold value for the matching rate set to the threshold input module or a current value of the real-time current waveform exceeds the threshold value for a current value set to the threshold input module, the detection module detects that the motor is in an abnormal state.

### Advantageous Effects

According to the present disclosure as described above, the smart motor control center with predictive maintenance function proposes a motor control center having a compact structure, which is capable of performing predictive maintenance for a motor connected to the motor control center by having, integrally formed with the motor control center in order to detect the operation state of the motor in real time, a current measurement module which measures a current flowing in a power supply line for supplying power from the motor control center to the motor, a detection server which detects the state of the motor on the basis of the measurement information of the current measurement module, and an image output module which outputs and provides the detection information of the detection server in the form of an image, thereby significantly saving a cost consumed to construct a predictive maintenance system in the related art and ensuring an excellent usability of a device without requesting a separate space for construction of the predictive maintenance system.

Moreover, the compact structure in which the current measurement module, the detection server, and the image output module are integrally formed with the motor control center is provided to minimize management manpower required for operating and managing the device, thereby ensuring excellent usability of the device.

### BRIEF DESCRIPTION OF DRAWINGS

FIG. 1 is a conceptual view of a smart motor control center with a predictive maintenance function according to an exemplary embodiment of the present disclosure.

FIGS. 2, 3 and 4 are views for explaining a smart motor control center with a predictive maintenance function illustrated in FIG. 1.

### DETAILED DESCRIPTIONS OF EXEMPLARY EMBODIMENTS

A smart motor control center with a predictive maintenance function according to a preferred exemplary embodiment of the present disclosure will be described in detail with reference to the accompanying drawings. A detailed description of known functions and configurations determined to unnecessarily obscure the gist of the present disclosure will be omitted.

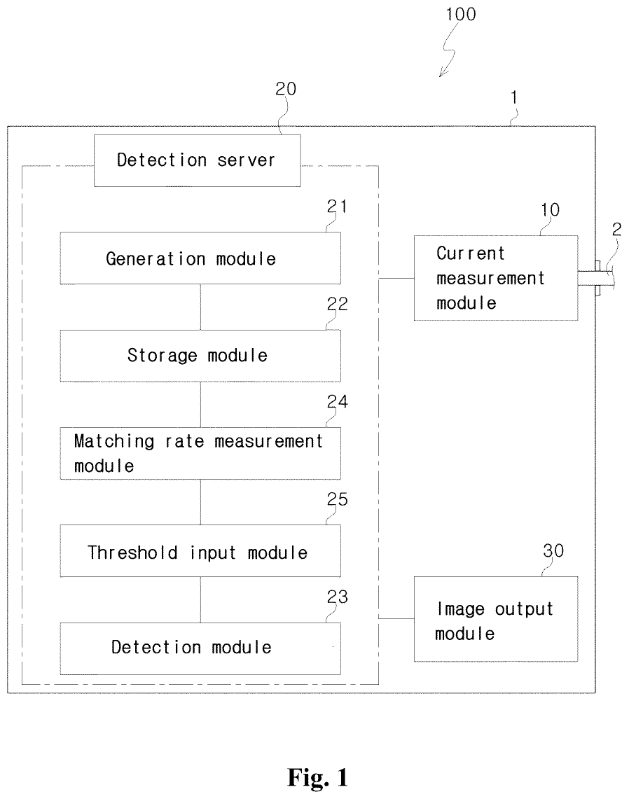

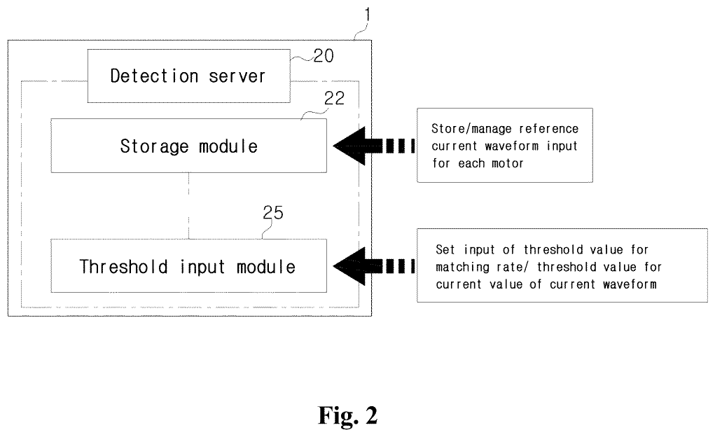

FIG. 1 is a conceptual view of a smart motor control center with a predictive maintenance function according to an exemplary embodiment of the present disclosure and FIGS. 2 to 4 are views for explaining a smart motor control center with a predictive maintenance function illustrated in FIG. 1, respectively.

As illustrated in FIG. 1, a smart motor control center with a predictive maintenance function according to an exemplary embodiment of the present disclosure is a motor control center (MCC) 1 which protects a motor 3 and a related loading device and includes a current measurement module 10, a detection server 20, and an image output module 30.

The current measurement module 10 measures a real-time current value flowing in a power supply line 2 which supplies power to the motor 3 and transmits measured current value information to the detection server 20 to be described below and at least one or more current measurement modules may be installed to be used.

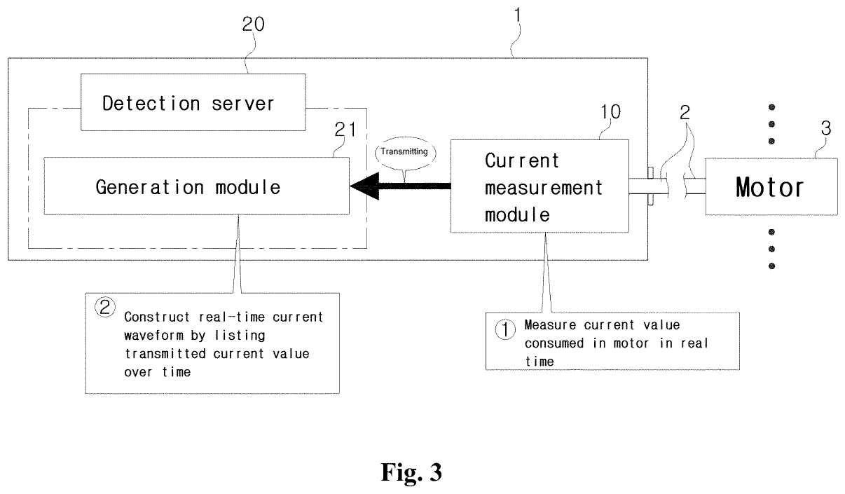

That is, as illustrated in FIG. 3, the current measurement module 10 measures a current (a current consumed to operate a motor) value which flows in real time in the power supply line 2 for supplying an operation power from the motor control center 1 to the motor 3 and transmits the measured current value information to the detection server 20. The measurement information is used as a basis for the detection server 20 to detect an operation state of the motor 3.

### Mode for Carrying Out the Disclosure

Here, when the motor control center 1 supplies power to a plurality of motors 3, the current measurement module 10 is individually installed in each power supply line 2 which supplies the power so that the real-time current value consumed in each motor 3 is measured and transmitted to allow the detection server 20 to detect a real-time operation state for each motor 3.

The detection server 20 detects a real-time operation state of the motor 3 on the basis of current value information measured and transmitted from the current measurement module 10 and includes a generation module 21 which lists current values measured and transmitted from the current measurement module 10 over time to construct a real-time current waveform for the motor 3, a storage module 22 which stores and manages a reference current waveform which is constructed by listing current values consumed in the motor 3 in a normally driven state of the motor 3 over time, and a detection module 23 which detects an operation state of the motor 3 in real time on the basis of a real-time current waveform of the motor 3 constructed in the generation module 21 and the reference current waveform stored in the storage module 22.

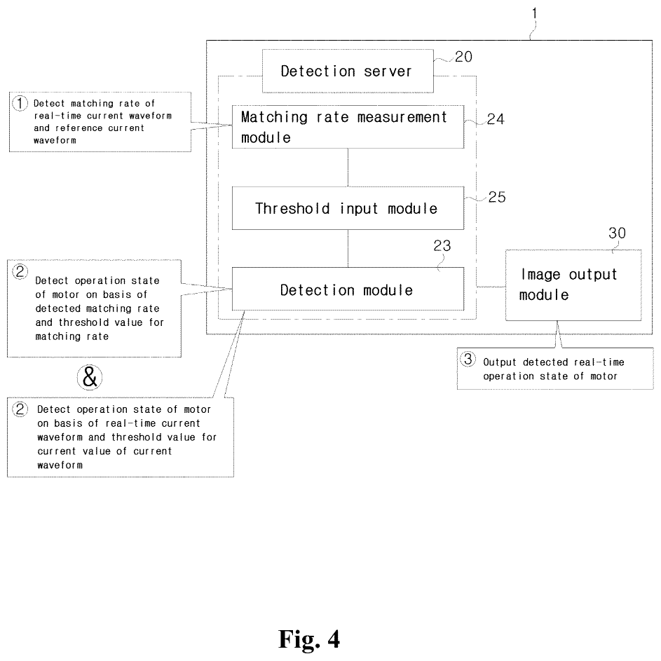

That is, as illustrated in FIG. 3, the generation module 21 of the detection server 20 lists current values measured by the current measurement module 10 over time and connects the listed current values in a straight line to construct the real-time current waveform for the motor 3 which operates in real time. As illustrated in FIG. 4, the detection module 23 detects an operation state of the motor 3 which is driven in real time on the basis of the real-time current waveform constructed in the generation module 21 and the reference current waveform stored in the storage module 22, which will be described in more detail below.

Here, the reference current waveform stored in the storage module 22 is a very stable (normal) waveform which is constructed on the basis of the current value measured from the motor in the normally driven state to ensure excellent reliability for a result obtained by analyzing and detecting a real-time current waveform on the basis of the reference current waveform.

Further, as illustrated in FIG. 1, the detection server 20 further includes: a matching rate measurement module 24 which measures a matching rate of the real-time current waveform to the reference current waveform by matching the real-time current waveform constructed in the generation module 21 and the reference current waveform stored in the storage module 22, and a threshold input module 25 which inputs and sets a threshold value for the matching rate of the real-time current waveform to the reference current waveform and a threshold value for a current value of the current waveform.

That is, as illustrated in FIG. 4, when a matching rate measured by the matching rate measurement module 24 exceeds the threshold value for the matching rate set to the threshold input module 25 or a current value of the real-time current waveform exceeds the threshold value for a current value set to the threshold input module 25, the detection module 23 detects that the motor 3 is in an abnormal state.

Here, the threshold value set by the threshold input module 25 is also set and managed directly by a user.

The image output module 30 outputs and provides the real-time operation state of the motor 3 detected by the detection server 20 as an image.

That is, as illustrated in FIG. 4, the image output module 30 is desirably formed to be exposed to the outside of the motor control center 1 to allow a manager to easily recognize a real-time operation state of the motor 3 by means of image information output through the image output module 30.

The smart motor control center 100 with a predictive maintenance function of the present disclosure configured by the above-described components proposes a motor control center having a compact structure, which is capable of performing predictive maintenance for a motor 3 connected to the motor control center 1 by having, integrally formed with the motor control center 1 in order to detect the operation state of the motor 3 in real time, a current measurement module 10 which measures a current flowing in a power supply line 2 for supplying power from the motor control center 1 to the motor 3, a detection server 20 which detects the state of the motor 3 on the basis of the measurement information of the current measurement module 10, and an image output module 30 which outputs and provides the detection information of the detection server 20 in the form of an image, thereby significantly saving a cost consumed to construct a predictive maintenance system in the related art and ensuring an excellent usability of a device without requesting a separate space for construction of the predictive maintenance system.

Moreover, the compact structure in which the current measurement module 10, the detection server 20, and the image output module 30 are integrally formed with the motor control center 1 is provided to minimize management manpower required for operating and managing the device, thereby ensuring excellent usability of the device.

The smart motor control center 100 with a predictive maintenance function according to the exemplary embodiment of the present disclosure configured by the above-described components operates as follows.

First, as illustrated in FIG. 2, the normal current waveform which is constructed by listing current values consumed in the motor 3 over time in a normally driven state of the motor 3 is repeatedly collected and reference current waveform information is constructed on the basis of the collected normal current waveform, and then the constructed reference current waveform is transmitted and stored in the storage module 22 of the detection server 20.

Here, the motor control center 1 may include a separate input port (not illustrated) which transmits information (data) to the storage module 22 to be stored and the reference current waveform information for the motor 3 may be simply stored and managed through the input port.

At this time, when a plurality of motors 3 is connected to the motor control center 1 to be used, reference current waveform information corresponding to each motor 3 may also be input and stored individually.

Simultaneously, the user sets a threshold value for the matching rate and a threshold value for a current value of the current waveform through the threshold input module 25 of the detection server 20 and the respective threshold values set as described may become a reference for detecting the operation state of the motor 3 which is driven in real time.

Thereafter, as illustrated in FIG. 3, the current measurement module 10 measures a current value consumed in the motor 3 which is driven in real time to transmit the current value to the generation module 21 of the detection server 20 and the generation module 21 lists current values which are transmitted in real time over time to construct a real-time current waveform for the motor 3.

By doing this, as illustrated in FIG. 4, the matching rate measurement module 24 of the detection server 20 detects a matching rate by matching a real-time current waveform constructed in the generation module 21 and a reference current waveform stored in the storage module 22 and the detection module 23 detects a real-time operation state of the motor by comparing the matching rate detected by the matching rate measurement module 24 and a threshold value for the matching rate set by the threshold input module 25.

Simultaneously, the detection module 23 detects a real-time operation state of the motor 3 by comparing a current value of a real-time current waveform constructed in the generation module 21 and a threshold value for a current value of a current waveform set by the threshold input module 25.

Here, the real-time operation state of the motor 3 detected by the detection module 23 of the detection server 20 is output and provided as an image by the image output module 30 to allow the user to clearly recognize the operation state of the motor 3.

The current measurement module 10, the detection server 20, and the image output module 30 which perform a series of processes as described above are integrally formed with the motor control center 1 to significantly reduce a time taken to collect information to detect an operation state of the motor 3 in real time, transmit and receive the information, and determine and detect a state of the motor on the basis of the information, thereby very quickly and accurately detecting a real-time operation state of the motor 3 to induce rapid response when an abnormal state of the motor occurs.

The present disclosure has been described with reference to the exemplary embodiment illustrated in the drawing, but the exemplary embodiment is only illustrative and the present disclosure is not limited thereto. Further, it would be appreciated by those skilled in the art that various modifications and equivalent exemplary embodiments may be made. Further, those skilled in the art may modify the present disclosure without departing from the spirit of the present disclosure. Accordingly, the scope of claiming the rights of the present disclosure is not defined within the scope of the detailed description, but may be limited by the following claims and the technical spirit thereof.

### INDUSTRIAL APPLICABILITY

The present disclosure is applicable to a predictive maintenance industry.

1. A smart motor control center with a predictive maintenance function which protects a motor and a related loading device, comprising:
one or more current measurement modules which measure a real-time current value flowing in a power supply line for supplying power to the motor and transmit measured current value information to a detection server;
the detection server which detects a real-time operation state of the motor on the basis of the current value information measured and transmitted from the current measurement module; and
an image output module which outputs and provides the real-time operation state of the motor detected by the detection server in a form of an image.

2. The smart motor control center with a predictive maintenance function according to claim 1, wherein the detection server includes:
a generation module which lists the current values measured and transmitted from the current measurement module over time to construct a real-time current waveform for the motor;
a storage module which stores and manages a reference current waveform which is constructed by listing current values consumed in the motor in a normally driven state of the motor over time; and
a detection module which detects the real-time operation state of the motor on the basis of the real-time current waveform of the motor constructed in the generation module and the reference current waveform stored in the storage module.

3. The smart motor control center with a predictive maintenance function according to claim 2, wherein the detection server further includes:
a matching rate measurement module which measures a matching rate of the real-time current waveform to the reference current waveform by matching the real-time current waveform constructed in the generation module and the reference current waveform stored in the storage module; and
a threshold input module which inputs and sets a threshold value for the matching rate of the real-time current waveform to the reference current waveform and a threshold value for a current value of the current waveform, respectively, and
when the matching rate measured by the matching rate measurement module exceeds the threshold value for the matching rate set to the threshold input module or the current value of the real-time current waveform exceeds the threshold value for the current value set to the threshold input module, the detection module detects that the motor is in an abnormal state.
